(19) United States
(12) Patent Application Publication
(10) Pub. No.: US 2016/0219698 A1
(43) Pub. Date: Jul. 28, 2016

(54) WIRING BOARD

(71) Applicant: KYOCERA Circuit Solutions, Inc., Kyoto (JP)

(72) Inventor: Masaharu YASUDA, Yasu-shi (JP)

(73) Assignee: KYOCERA Circuit Solutions, Inc., Kyoto (JP)

(21) Appl. No.: 15/001,362

(22) Filed: Jan. 20, 2016

(30) Foreign Application Priority Data
Jan. 26, 2015 (JP) 2015-011947

(51) Int. Cl. H05K 1/02

(52) U.S. Cl. CPC H05K 1/0296

(57) ABSTRACT

A wiring board of the present invention includes a build-up layer having a plurality of insulating layers laminated one upon another, a groove formed on a major surface of each of the insulating layers, and a wiring conductor formed in the groove. A surface of the wiring conductor lies lower than the major surface of each of the insulating layers which is formed in the wiring conductor in the groove.

### BACKGROUND OF THE INVENTION

1. Field of the Invention

The present invention relates to a wiring board having high-density fine wiring.

2. Description of the Related Art

FIG. 3 shows a schematic sectional view of a conventional wiring board C having high-density fine wiring. The wiring board C is obtained by laminating a build-up portion 42 on upper and lower surfaces of a core substrate 41. The core substrate 41 includes a core insulating plate 43 and a core wiring conductor 44. The build-up portion 42 is formed of build-up insulating layers 45a to 45d, a build-up wiring conductor 46, and a protective solder resist layer 47. At the center of the upper surface of the wiring board C, there is formed amounting portion 48 on which a semiconductor element is mounted.

The core insulating plate 43 has a plurality of through holes 49 penetrating from an upper surface to a lower surface of the insulating plate 43. The core wiring conductor 44 is deposited on the upper and lower surfaces of the insulating plate 43 and in the through holes 49.

The build-up insulating layers 45a to 45d are laminated in pairs on both surfaces of the core substrate 41. Each of the insulating layers 45a to 45d also has a plurality of via holes 50 penetrating from an upper surface to a lower surface thereof. Each of the insulating layers 45a to 45d has a plurality of grooves 51 in a surface thereof. The build-up wiring conductor 46 is deposited in the via holes 50 and the grooves 51 in each of the insulating layers 45a to 45d. The wiring conductor 46 is filled with the grooves 51 so as to be flush with the surface of each of the insulating layers 45a to 45d.

A part of the wiring conductor 46 deposited on the surface of the insulating layer 45b that is the outermost layer on an upper surface side forms a semiconductor element connection pad 52 to be connected to a semiconductor element. Apart of the wiring conductor 46 deposited on the surface of the insulating layer 45d that is the outermost layer on a lower surface side forms an external connection pad 53 to be connected to an external circuit board.

The solder resist layer 47 is formed on the surface of each of the outermost insulating layers 45b and 45d. The solder resist layer 47 on the upper surface side has an opening 47a to expose the semiconductor element connection pad 52. The solder resist layer 47 on the lower surface side has an opening 47b to expose the external connection pad 53.

By connecting an electrode of the semiconductor element to the semiconductor element connection pad 52, and connecting the external connection pad 53 to the wiring conductor of the external electric circuit board, the semiconductor element is electrically connected to the external electric circuit board. This conventional wiring board is described in, for example, Japanese Unexamined Patent Publication No. 2006-41029.

Meanwhile, with the advance of downsizing and higher function of electronic devices represented by portable communication devices and music players, there is also a demand for downsizing and higher function of wiring boards mounted on these electronic devices. Hence, in the build-up wiring conductors on the wiring boards, fine wiring conductors whose width and intervals are respectively, for example, 5 μm or less are to be formed at high density.

However, in the conventional wiring board C, the build-up wiring conductor 46 is formed so as to be flush with the surface of each of the insulating layers 45a to 45d. Consequently, the surface of the wiring conductor 46 has a height identical with that of an interface between the insulating layer 45a or 45c and the insulating layer 45b or 45d, and an interface between the insulating layer 45b or 45d and the solder resist layer 47. These interfaces are physically and chemically weak, thus making it easier for metal ions to move along these interfaces. This leads to the problem that electrical insulation reliability between the wiring conductors adjacent to each other may be poor particularly in the fine high-density wiring as described above.

### SUMMARY OF THE INVENTION

An embodiment of the present invention has an object to provide a high-density wiring board having excellent insulation reliability.

The wiring board according to the embodiment of the present invention includes a build-up layer having a plurality of insulating layers laminated one upon another, a groove formed on a major surface of each of the insulating layers, and a wiring conductor formed in the groove. A surface of the wiring conductor lies lower than the major surface of each of the insulating layers which is formed in the wiring conductor in the groove.

With the wiring board according to the embodiment of the present invention, the wiring conductor is formed in the groove formed on the major surface of each of the insulating layers. Further, the surface of the wiring conductor formed in the groove lies at the location lower than the major surface of each of the insulating layers in which the wiring conductor is partially formed. Even though spacing between the wiring conductors adjacent to each other remains unchanged, it is possible to increase an interface distance that connects the wiring conductors along the interface between the insulating layers. This ensures insulation properties between the wiring conductors adjacent to each other. Furthermore, the interface is formed of a horizontal interface and a vertical interface, and metal ion movement is effectively inhibited by the vertical interface. It is consequently possible to provide the wiring board having high-density wiring with excellent insulation reliability.

### BRIEF DESCRIPTION OF THE DRAWINGS

FIG. 1 is a schematic sectional view showing a wiring board according to one embodiment of the present invention;

FIG. 2 is a schematic sectional view showing a wiring board according to another embodiment of the present invention; and

FIG. 3 is a schematic sectional view showing a conventional wiring board.

### DESCRIPTION OF THE EMBODIMENTS

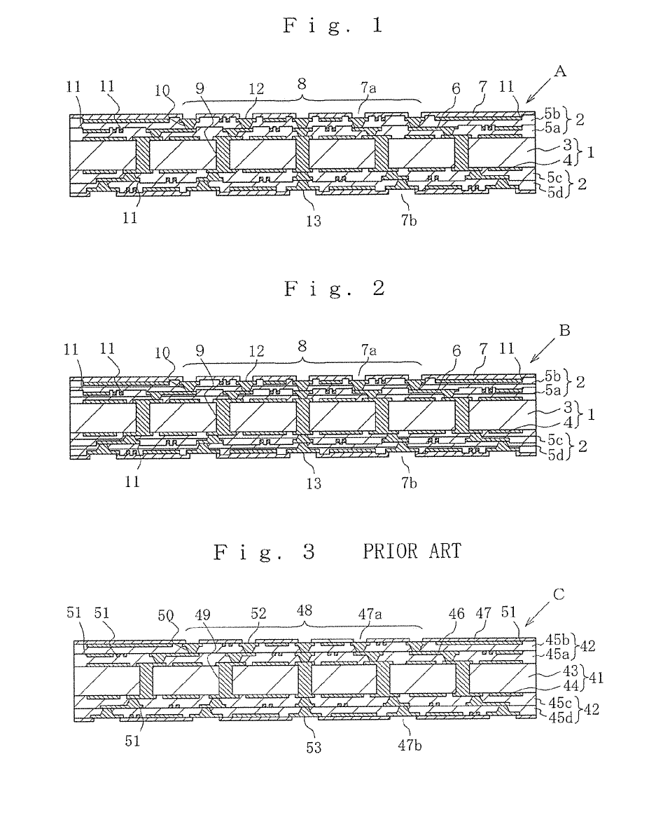

A wiring board according to one embodiment is described with reference to FIG. 1. The wiring board A shown in FIG. 1 is obtained by laminating a build-up portion 2 on upper and lower surfaces of a core substrate 1. The core substrate 1 includes a core insulating plate 3 and a core wiring conductor 4. The build-up portion 2 is formed of build-up insulating layers 5a to 5d, a build-up wiring conductor 6, and a protective solder resist layer 7. At the center of the upper surface of the wiring board A, there is formed a mounting portion 8 on which a semiconductor element is mounted.

The core insulating plate 3 has a plurality of through holes 9 penetrating from an upper surface to a lower surface thereof. The core wiring conductor 4 is deposited on the upper and lower surfaces of the insulating plate 3 and in the through holes 9. The wiring conductor 4 in the through holes 9 establishes continuity between the wiring conductors 4 formed on the upper and lower surfaces of the insulating plate 3. The insulating plate 3 is formed of an insulating material obtained by, for example, impregnating a glass cloth with epoxy resin, bismaleimide triazine resin, or the like, followed by thermosetting. The through holes 9 are formed by, for example, drilling, laser processing, or blast processing.

The build-up insulating layers 5a to 5d are laminated in pairs on both surfaces of the core substrate 1. Each of the insulating layers 5a to 5d also has a plurality of via holes 10 penetrating from an upper surface to a lower surface thereof. Each of the insulating layers 5a to 5d has a groove 11 on a surface thereof that is the side opposite the core substrate 1. The build-up wiring conductor 6 is formed in the via holes 10 and the groove 11. The wiring conductor 6 in the via holes 10 establishes continuity between the wiring conductors 6 located above and below with the insulating layers 5a to 5d interposed therebetween, or between the wiring conductor 6 and the wiring conductor 4.

The insulating layers 5a to 5d are formed of an insulating material obtained by thermosetting, for example, bismaleimidetriazine resin, polyimide resin, or the like. The via holes 10 or the groove 11 is formed by, for example, laser processing.

The wiring conductor 6 is formed in the via holes 10 and the groove 11 of the insulating layers 5a to 5d as described above. A part of the wiring conductor 6 deposited on the surface of the outermost insulating layer 5b on the upper surface side functions as a semiconductor element connection pad 12 to be connected to the semiconductor element. A part of the wiring conductor 6 deposited on the surface of the outermost insulating layer 5d on the lower surface side functions as an external connection pad 13 to be connected to an external circuit board. The wiring conductors 4 and 6 are formed of a satisfactorily conductive metal, such as copper foil and copper plating, and are formed by well-known subtractive method, semi-additive method, or the like.

The solder resist layer 7 is formed on the surface of each of the outermost insulating layers 5b and 5d. The solder resist layer 7 is formed of a thermosetting resin, such as polyimide resin. The solder resist layer 7 on the upper surface side has an opening 7a to expose the semiconductor element connection pad 12. The solder resist layer 7 on the lower surface side has an opening 7b to expose the external connection pad 13.

By connecting an electrode of the semiconductor element to the semiconductor element connection pad 12, and connecting the external connection pad 13 to the wiring conductor of the external electric circuit board, the semiconductor element is electrically connected to the external electric circuit board.

In the wiring board A shown in FIG. 1, a surface of the wiring conductor 6 in the via holes 10 and the groove 11 of each of the insulating layers 5a to 5d is located closer to the core substrate 1 than an interface between the laminated insulating layers 5a and 5b, an interface between the insulating layers 5c and 5d, an interface between the insulating layer 5b and the solder resist layer 7, and an interface between the insulating layer 5d and the solder resist layer 7. That is, the surface of the wiring conductor 6 is not flush with the major surface of each of the insulating layers 5a to 5d in which the wiring conductor 6 is partially formed, and lies lower than the major surface of each of the insulating layers 5a to 5d. Depending on a thickness of the insulating layers 5a to 5d and spacing between the wiring conductors 6, the surface of the wiring conductor 6 preferably lies approximately 0.5-5 μm lower than the major surface of each of the insulating layers 5a to 5d.

For example, the surface of the wiring conductor 6 lies closer to the core substrate 1 by approximately 2 μm from a boundary surface.

That is, for example, when spacing between the wiring conductors 6 disposed adjacent to each other is 3 μm, an interface distance that connects the wiring conductors 6 adjacent to each other along an interface having weak insulating properties can be increased up to approximately 7 μm by lowering the surface of the wiring conductor 6 by approximately 2 μm. This ensures insulating properties between the wiring conductors 6 adjacent to each other. Furthermore, the interface is formed of a horizontal interface and a vertical interface, and metal ion movement is effectively prevented by the vertical interface. It is consequently possible to provide the wiring board having high-density wiring with excellent insulation reliability.

No particular limitation is imposed on a method with which the surface of the wiring conductor 6 in the via holes 10 and the groove 11 of each of the insulating layers 5a to 5d is located closer to the core substrate 1 than the interface between the laminated insulating layers 5a and 5b, the interface between the insulating layers 5c and 5d, the interface between the insulating layer 5b and the solder resist layer 7, and the interface between the insulating layer 5d and the solder resist layer 7. For example, an employable method includes forming a satisfactorily conductive metal, such as copper plating, into the via holes 10 and the groove 11, and then reducing the thickness of the conductive metal by etching.

The present invention is not limited to the one embodiment as described above, and various modifications are possible as long as they are within the scope of the claims. For example, with the above embodiment, each of the insulating layers 5a to 5d has a single-layer structure. Alternatively, each of the insulating layers 5a to 5d may have a two-layer structure as shown in FIG. 2. In this case, a portion of each of the insulating layers which forms the groove 11 is made into a layer containing less or no inorganic filler, and a portion of each of the insulating layers which does not form the groove 11 is made into a layer containing a large amount of the inorganic filler.

Owing to the two-layer structure, the layer in which the fine high-density wiring conductor 6 is disposed in the groove 11 can be made into a layer that is less apt to cause a gap between the inorganic filler and an insulating resin, thus having more excellent insulation properties. With the layer including no groove 11, physical property values, such as coefficient of thermal expansion, is controllable by adjusting the kind and amount of the inorganic filler. Thus, the wiring board having two advantages is obtained by employing the two-layer structure.

The foregoing embodiment exemplifies the wiring board A including the core substrate 1. The foregoing embodiment maybe applied to a coreless substrate without the core substrate 1.

What is claimed is:

1. A wiring board comprising:
a build-up layer comprising a plurality of insulating layers laminated one upon another;
a groove formed on a major surface of each of the insulating layers; and
a wiring conductor formed in the groove,
wherein a surface of the wiring conductor lies lower than the major surface of each of the insulating layers which is formed in the wiring conductor in the groove.

2. The wiring board according to claim 1, wherein the build-up layer comprises the two insulating layers, and the major surface of each of the insulating layers has the groove formed in the wiring conductor.

3. The wiring board according to claim 1, further comprising a core substrate,
wherein the build-up layer is disposed on at least one surface of the core substrate.

4. The wiring board according to claim 1, wherein at least one of the insulating layers has a two-layer structure.
